(19) United States
(12) Patent Application Publication
(10) Pub. No.: US 2007/0132442 A1
(43) Pub. Date: Jun. 14, 2007

(54) Filter tuning

(76) Inventor: Philip Matthew Jones, Cambridge (GB)

Correspondence Address: FISH & RICHARDSON PC, P.O. BOX 1022, MINNEAPOLIS, MN, 55440-1022, US

(21) Appl. No.: 11/301,096

(22) Filed: Dec. 12, 2005

(51) Int. Cl. G01R 23/165

(52) U.S. Cl. 324/76.29

(57) ABSTRACT

Calibrating a filter includes configuring a connection network coupled to input and output ports of first and second processing components into a first state in which the first and second processing components are connected to form at least part of an oscillator, and reconfiguring the connection network into a second state in which the first and second processing components are connected to form at least part of a polyphase filter.

### BACKGROUND

The invention relates to filter tuning.

The IEEE 802.15.4 standard and the ZigBee™ standard provide communication protocols for relaxed throughput, low power consumption wireless communication applications, for example, ad-hoc wireless networking applications. Different kinds of physical layer components can be used provide the functionality specified by these higher layer protocols. Various integrated circuit designs have been proposed to implement these physical layer components that include radio frequency (RF) components and other analog and digital circuitry. For example, one component that facilitates reliable RF communication in a compact device is an on-chip polyphase bandpass filter.

### SUMMARY

In one aspect, in general, the invention features an apparatus including a first processing component having an input port and an output port, a second processing component having an input port and an output port, and a reconfigurable connection network coupled to the ports. The reconfigurable connection network has at least two connection states including a first state in which the first and second processing components are connected to form at least part of a polyphase filter, and a second state in which the first and second processing components are connected to form at least part of an oscillator.

In another aspect, in general, the invention features a method, and corresponding system, for calibrating a filter. The method includes configuring a connection network coupled to input and output ports of first and second processing components into a first state in which the first and second processing components are connected to form at least part of an oscillator; and reconfiguring the connection network into a second state in which the first and second processing components are connected to form at least part of a polyphase filter.

Aspects of the invention may include one or more of the following features.

Tuning circuitry is configured to switch between the connection states, measure an operating characteristic of the oscillator, and tune an operating characteristic of the polyphase filter based at least in part on the measured operating characteristic of the oscillator.

The operating characteristic of the oscillator includes an oscillation frequency of the oscillator.

The operating characteristic of the polyphase filter includes phase shifts imparted by the first and second processing components to a signal at an operating frequency.

Tuning the operating characteristic of the polyphase filter includes tuning the phase shifts based on a relationship between the oscillation frequency and the operating frequency.

Tuning the operating characteristic of the polyphase filter includes tuning tunable elements in the first and second processing components. The tunable elements can include tunable capacitors, such as unit capacitors each having a capacitance that is a multiple of a unit capacitance value.

In the first state, the input port of the first processing component receives a first input signal and the input port of the second processing component receives a second input signal, and a first connection couples the output port of the first processing component to the input port of the second processing component and a second connection couples the output port of the second processing component to the input port of the first processing component.

The first input signal includes an in-phase signal derived from a received signal modulated by a first sinusoidal signal, and the second input signal includes a quadrature-phase signal derived from the received signal modulated by a second sinusoidal signal that has a 90 degree phase shift relative to the first sinusoidal signal.

In the first state, the first connection includes a 180 degree phase shift relative to the second connection.

The apparatus further includes a third processing component having an input port and an output port, and a fourth processing component having an input port and an output port. In the first state, ports of the third and fourth processing component are connected to form at least part of the polyphase filter. In the second state, the first, second, third, and fourth processing component are connected to form at least part of the oscillator.

In the first state, the input port of the third processing component receives a signal from the output port of the first processing component and the input port of the fourth processing component receives a signal from the output port of the second processing component, and a third connection couples the output port of the third processing component to the input port of the fourth processing component and a fourth connection couples the output port of the fourth processing component to the input port of the third processing component.

The first and second processing components each include a filter.

The first and second processing components each include a low-pass filter.

The input ports and output ports of the first and second processing components couple differential signals.

The apparatus further includes at least a first gain element in the oscillator. The gain element can include a limiter.

The apparatus further includes a second gain element in the oscillator, where the position of the second gain element with respect to the second processing component is symmetric with the position of the first gain element with respect to the first processing component.

The apparatus further includes a phase element in the oscillator that provides negative feedback for low frequencies.

Aspects of the invention may include one or more of the following advantages.

A reconfigurable connection network enables and oscillation approach for tuning characteristics of a polyphase filter. Measuring an operating characteristic of an oscillator formed from components of the polyphase filter provides information that can be used to accurately tune an operating characteristic of the polyphase filter. Various features of the filter components and the connection network contribute to the efficiency and accuracy of the calibration process. For example, using unit capacitors which can be tuned together as tunable elements throughout various components enables both the filter bandwidth and the center frequency of the polyphase filter to be tuned together. Maintaining symmetry in the placement of components in the in-phase and quadrature-phase portions of the reconfigurable connection network contributes to the accuracy of the tuning procedure.

Other features and advantages of the invention will become apparent from the following description, and from the claims.

### DESCRIPTION OF DRAWINGS

FIGS. 1A and 1B are block diagrams of an integrated circuit.

FIG. 1C is a block diagram of reconfigurable circuitry.

FIGS. 2A-2J are spectral plots illustrating filter operation.

FIG. 3A is a block diagram of a filter circuit.

FIG. 3B is a spectral plot of a frequency response.

FIGS. 4A and 4B are block diagrams of configurations of reconfigurable circuitry.

FIG. 5A is circuit diagram of a low-pass filter.

FIG. 5B is a circuit diagram of a polyphase filter.

FIG. 5C is a circuit diagram of an oscillator.

FIG. 6A is a plot of an input-output transfer function.

FIG. 6B is a plot of a gain function.

FIG. 7A-7C are plots of phase responses.

### DESCRIPTION

1 Overview

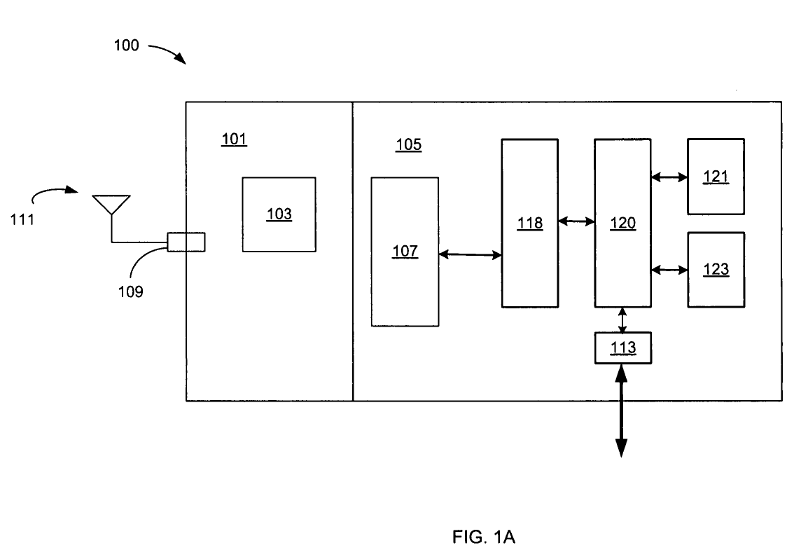

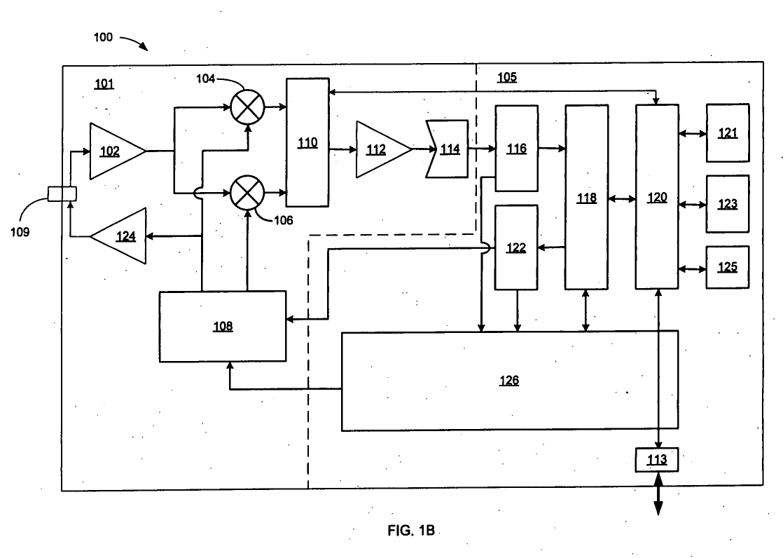

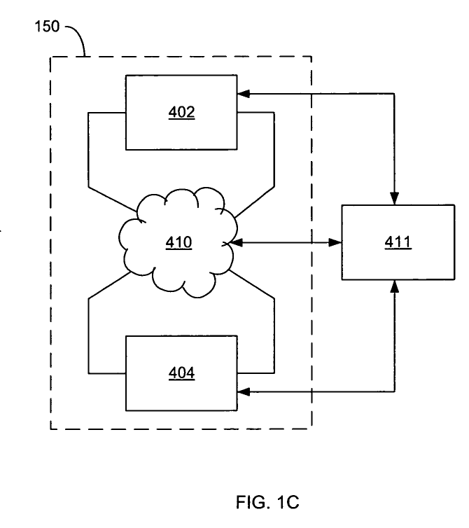

Referring to FIG. 1A, an integrated circuit (IC) 100 is configurable for use in a variety of wireless networking environments based on the IEEE 802.15.4 physical (PHY) and medium access control (MAC) layers including, e.g., the ZigBee™ networking environment and the EmberNet™ networking environment. The IC 100 can be used in both full functionality devices (FFD) and reduced functionality devices (RFD). The IC 100 uses a small number of external components to provide a radio transceiver that includes an on-chip microprocessor 120 for execution of protocol stack software and custom application software. The configurable nature of the IC 100 is not required in all embodiments of the approaches described below.

The IC 100 implements a radio transceiver containing analog circuitry 101 including a super heterodyne receiver 103, other frequency synthesis and timing circuitry, and digital circuitry 105 including baseband (BB) signal processing circuitry 107 and other data processing control circuitry.

Referring to FIG. 1B, the receiver 103 uses an on-chip polyphase band-pass filter 110 to extract an intermediate frequency (IF) signal that has been demodulated from a received RF signal for a desired channel. The polyphase band-pass filter 110 is tunable using an approach in which components of the filter 110 are reconfigured as an oscillator. The oscillation frequency of the oscillator enables tuning of the operating frequency at which the filter 110 has a desired phase response, as described in more detail below. Various control signals and analog/digital conversion components provide an interface between the analog circuitry 101 and digital circuitry 105.

Referring again to FIG. 1A, the analog circuitry 101 includes an interface 109 to an RF antenna 111 for reception and transmission of RF signals. The RF antenna 111 is provided, for example, as part of the device that incorporates the IC 100. For RF reception, the super heterodyne receiver demodulates a received RF signal for one of a set of channels with RF frequencies (e.g., near 2.4 GHz) to an IF signal (e.g., 4 MHz). The analog circuitry converts this IF signal to a digital signal that is further demodulated to a BB signal by the digital circuitry 105. For RF transmission, the analog circuitry 101 modulates an RF signal at one of the channel frequencies using Minimum Shift Keying (MSK) modulation (also known as Offset Quadrature Phase Shift Keying (O-QPSK) with half-sine pulse shaping) with direct sequence spread spectrum (DSSS) modulated data provided by the digital circuitry 105. In other implementations, other forms of modulation can be used, with or without spread spectrum modulation.

The digital circuitry 105 includes a microprocessor 120 that includes a memory controller to access a flash memory module 121 (e.g., for storing executable software) and a RAM memory module 123 (e.g., for storing data). The microprocessor 120 includes a serial interface 113 that can be used to test and characterize various functions of the IC 100. Also, the serial interface 113 can be used to load executable software into the flash memory module 121 either directly, or optionally, by downloading a boot program into the RAM memory module 123 which the microprocessor 120 uses to first download software blocks into the RAM memory module 123 and then copy the blocks into the flash memory module 121.

The digital circuitry 105 also includes a lower MAC module 118 that interfaces with the microprocessor 120 sending and receiving packet data, and with the BB signal processing circuitry 107 sending and receiving packets with MAC layer information (called “frames”). The lower MAC module 118 handles various MAC layer functions including, for example, cyclic redundancy check (CRC) codes, packet acknowledgements, and backoff timing.

Referring again to FIG. 1B, an exemplary implementation of the super heterodyne receiver 103 includes a low-noise amplifier (LNA) 102 that provides an amplified version of the RF signal received over the RF antenna interface 109. An in-phase (I) mixer 104 and a quadrature-phase (Q) mixer 106 mix the RF signal with a local oscillator (LO) signal provided by a frequency synthesizer 108 to provide I and Q signals to the polyphase band-pass filter 10. The frequency synthesizer 108 tunes the LO signal to the difference between a desired RF channel and the 4 MHz IF frequency. The polyphase band-pass filter 110 and an IF amplifier 112 provide an IF signal containing the information content of the desired RF channel. An analog-to-digital converter (ADC) 114 samples the IF signal faster than the 8 MHz Nyquist rate, e.g., at 12 MHz.

The BB signal processing circuitry 107 includes a BB receiver 116 and a BB transmitter 122. The digital signal processing performed by the BB receiver 116 and the BB transmitter 122 can be implemented in software, hardware, or a combination of software and hardware.

The BB receiver 116 performs coherent demodulation using an LO signal at the IF frequency from a phase-locked loop (PLL). The preamble of the demodulated signal is used to achieve frequency, phase and symbol timing lock with the received signal. The BB receiver 116 uses dithering and severe quantization to determine a phase error from a correlation signal for adjusting the PLL. The BB receiver 116 recovers the DSSS modulated data in the BB signal by sampling the bits or “chips” of a symbol's spreading sequence and despreading to recover the data bits.

The BB transmitter 122 directly modulates the output of the frequency synthesizer 108 with the information in a frame. The resulting frequency synthesizer signal is amplified by a power amplifier 124 and coupled over the interface 109 to the RF antenna 111. The BB transmitter 122 includes a spreader for processing the frame bits provided by the lower MAC module 118. The spreader converts a sequence of frame bits at a bit rate of R_{b} (e.g., 250 kbps for ZigBee™) into a DSSS modulated sequence of chips at a chip rate of R_{c} (e.g., 2 Mchips/sec for ZigBee™). This chip sequence is used to modulate the frequency synthesizer 2.4 GHz carrier wave.

An encryption module 125 is coupled to the microprocessor 120 via a register block interface. The encryption module 125 can implement, for example, the Advanced Encryption Standard (AES). The encryption module 125 provides hardware acceleration for encryption.

The IC 100 includes other analog and digital timing and control circuitry 126 that includes, for example, an interrupt controller, IC power management and internal oscillators.

2 Polyphase Filter

The IC 100 performs an initialization procedure (e.g., when the IC 100 is powered up, or initially after fabrication) to set various characteristics of the IC 100, including a tuning procedure for the polyphase band-pass filter 110. The IC 100 uses an oscillation approach to tune characteristics of the polyphase filter 110 including, for example, its bandwidth and center frequency. The oscillation approach includes reconfiguring processing components of the polyphase filter 110 to form an oscillator whose oscillation frequency can be used to tune the filter 110.

Referring to FIG. 1C, reconfigurable circuitry 150 includes a first processing component 402, and a second processing component 404 interconnected by a reconfigurable connection network 410. The connection network 410 has at least two connection states. In a first state, the first and second processing components 402 and 404 are connected to form at least part of the polyphase filter 110. In a second state, the first and second processing components 402 and 404 are connected to form at least part of an oscillator. For example, cross-coupled processing components for in-phase and quadrature-phase inputs of the polyphase filter 110 can be connected in series to form an oscillator, as described in more detail below.

Tuning circuitry 411 is able to reconfigure the connection network 410 to switch between the connection state. The tuning circuitry 411 is also able to measure an operating characteristic of the oscillator, such as its oscillation frequency. The tuning circuitry 411 uses this measurement to determine how to tune one or more operating characteristics of the polyphase filter 110. For example, the bandwidth and center frequency of the polyphase filter 110 are determined by values of tunable elements of the processing components 402 and 404. The center frequency may need to be adjusted to precisely tune the phase shifts imparted by the processing components to a signal at an operating frequency. These phase shifts can be tuned by adjusting the tunable elements in the processing components 402 and 404. The tuning circuitry 411 can be implemented, for example, by the microprocessor 120 using software control of the tunable elements, and software control of switches (e.g., transistors) to form and/or break connections in the connection network 410.

In some implementations, the polyphase filter 110 uses “unit capacitors” as tunable elements throughout various components which can be tuned together such that each capacitance in the polyphase filter 110 is a multiple of a unit capacitance value C(x), where x represents a control input value that tunes the capacitance value C(x). These unit capacitors enables the circuitry of the polyphase filter 110 to be designed such that the ratio of filter's bandwidth to the filter's center frequency remains constant as the value of C(x) is tuned (e.g., when both the bandwidth and center frequency are proportional to the unit capacitance). Thus, with appropriate choice of this ratio, both the filter bandwidth and the center frequency can be tuned to desired values by tuning the unit capacitance value C(x), as described in more detail below.

2.1 Polyphase Filter Operation

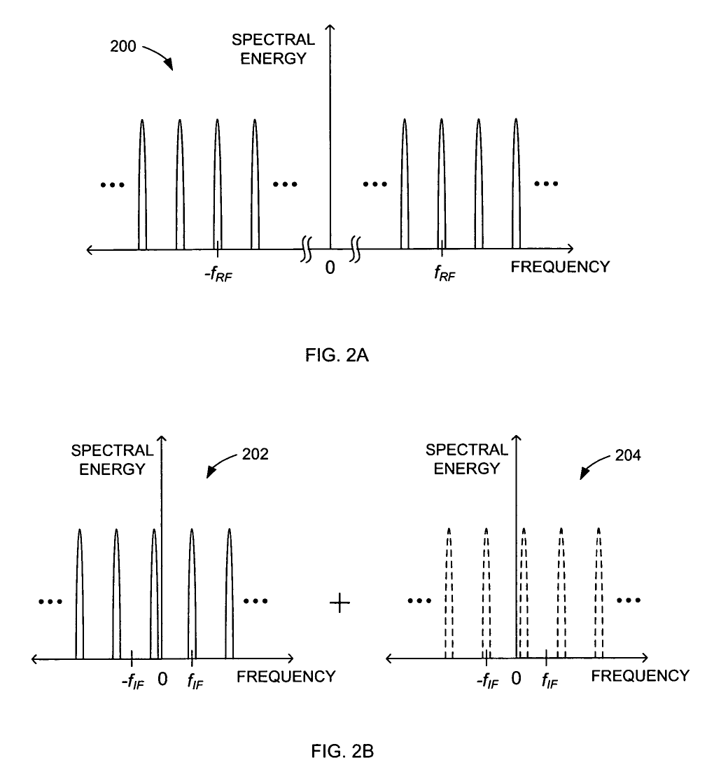

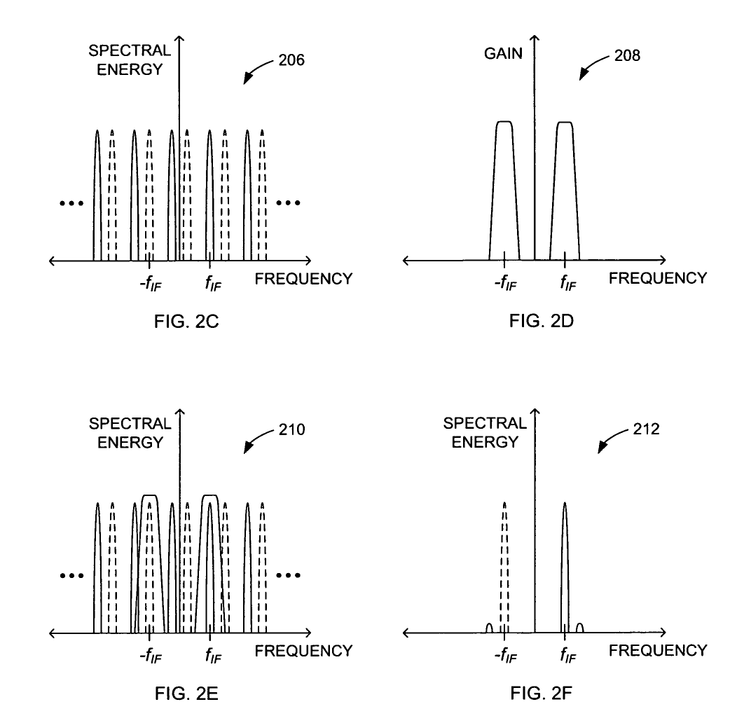

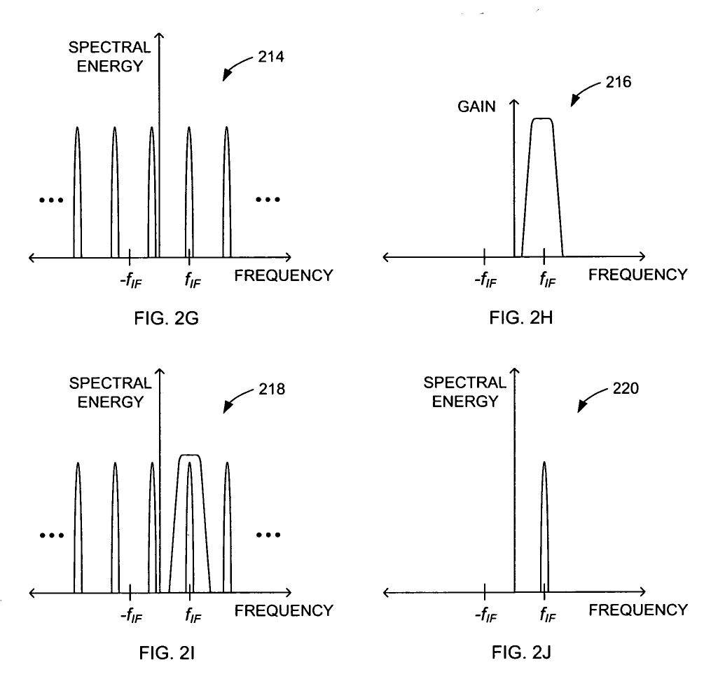

As described above, the polyphase filter is used to extract an IF signal that has been demodulated from a received RF signal for a desired channel. FIG. 2A shows a spectrum 200 (spectral energy vs. frequency) made up of a series of narrowband channel spectra for a set of RF channels including a channel with a center frequency of f_{RF}. In this example, the channel spacing is 5 MHz. A real signal at this frequency has energy at both positive and negative frequencies (i.e., centered at f_{RF} and −f_{RF}, as illustrated). The polyphase band-pass filter implements a “complex” band-pass filter using cross-coupled low-pass filter components acting on two demodulated input signals. This polyphase configuration is able to provide certain advantages over a “real” band-pass filter acting on a single demodulated input signal.

For example, FIGS. 2B-2F illustrate the operation of a single-input (or “real”) band-pass filter in which the RF channel at f_{RF} is demodulated to an intermediate frequency of f_{IF} by multiplication by a real sinusoidal signal cos(2πft) having a frequency f=f_{RF}−f_{IF}. Referring to FIG. 2B, the effects of multiplication by this sinusoid can be seen in the frequency domain as a sum of two spectra 202 and 204 corresponding to convolution of the channel spectra 200 by the positive and negative spectral components of the sinusoid, respectively. FIG. 2C shows the resulting demodulated spectrum 206 (where the solid line represents the spectral components originating from spectrum 202, and the dashed line represents the spectral components originating from spectrum 204).

Referring to FIG. 2D, a real band-pass filter, having a frequency response 208, filters the demodulated signal to extract the narrowband channel which has been shifted to a frequency of f_{IF} (with positive and negative frequency components). In some cases, the width and roll-off of the filter frequency response 208 is such that a small “image” signal leaks through the filter, as shown by the overlapped spectra 210. As shown in FIGS. 2E and 2F, the width and roll-off of the filter is such that the spectrum 212 of the resulting extracted signal includes energy from a channel which is close to the “image frequency” (a distance of 2f_{IF} from the desired RF channel frequency). In the illustrated example, the relationship between the IF frequency and the channel spacing is such that no channel is centered at the image frequency, however, depending on the filter frequency response, some energy can leak through.

FIGS. 2G-2J illustrate the operation of a “complex” band-pass filter in which the RF channel at f_{RF} is demodulated to an intermediate frequency of f_{IF} by multiplication by a complex exponential signal exp(i2πft) having a frequency f=f_{RF}−f_{IF}. Referring to FIG. 2G, the effects of multiplication by this complex exponential signal can be seen in the frequency domain as spectrum 214 corresponding to convolution of the channel spectra 200 by the single positive spectral component of the complex exponential signal.

Referring to FIG. 2H, a complex band-pass filter, having a frequency response 216, filters the demodulated signal to extract the narrowband channel which has been shifted to a frequency of f_{IF} (with only a positive frequency component). Even if the tolerances for the width and/or roll-off of the complex filter are relaxed (e.g., the width of the frequency response 216 is larger than the width of the positive frequency band of the frequency response 208), the complex band-pass filter provides greater rejection of signal energy from other channels than the real band-pass filter, as shown by the overlapped spectra 218 (FIG. 2I). As shown in FIG. 2J, the spectrum 220 of the resulting extracted signal includes the desired channel spectrum isolated from neighboring channels as well as any channels having signal energy near the image frequency. While this example is described using complex-valued signals, the analysis also applies to the polyphase (or “complex”) filter implementation described below which operates on real-valued signals.

A complex signal x(t) can be represented by two real signals, an in-phase signal x_{I}(t) and a quadrature-phase signal x_{Q}(t), according to x(t)=x_{I}(t)+jx_{Q}(t). For example, in the analysis above, the complex exponential can be represented as:
exp(j2πft)=cos(2πft)+j sin(2πft).
The receiver 103 multiplies the incoming RF signal by this complex exponential using the I mixer 104 to provide the real part of the product x_{I}(t)=x_{RF}(t) cos(2πft), and the Q mixer 106 to provide the imaginary part of the product x_{Q}(t)=x_{RF}(t) sin(2πft). These two real signals x_{I}(t) and x_{Q}(t) are the inputs to the polyphase band-pass filter 110.

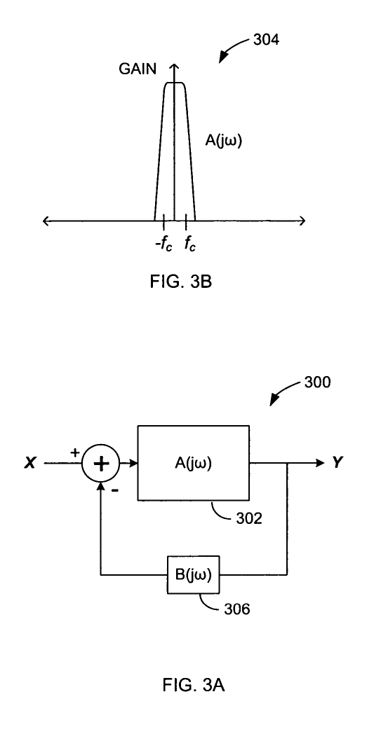

Before turning to an exemplary implementation of a polyphase band-pass filter that receives two real input signals, FIG. 3A illustrates an implementation of a polyphase band-pass filter that receives the complex signal x(t). The filter circuit 300 illustrates how a filter having an asymmetric frequency response 216 can be constructed from a low-pass filter 302 having a symmetric frequency response A(iω) with a cutoff frequency f_{c}, and a feedback gain component 306 having a frequency response B(jω). The circuit 300 relates the Fourier transform X(jω) of the input signal x(t) to the Fourier transform Y(jω) of the output signal y(t) to according to the equation:

$$Y ( j ω ) = H ( j ω ) X ( jω ) = \frac{1}{\frac{1}{A ( jω )} + B ( jω )} X ( jω ) .$$

Therefore, when A(jω) corresponds to the low-pass frequency response 304 (FIG. 3B) expressed as

$$A ( jω ) = {H}_{LP} ( jω ) = \frac{{ω}_{c}}{{ω}_{c} + jω} ,$$

where ω_{c}=2πf_{c} (corresponding to a Laplace transform with a single pole on the negative real axis), and B(jω) corresponds to a complex gain B(jω)=−jω_{IF}/ω_{c}, then the frequency response H(jω) of the circuit 300 is

$$H ( jω ) = {H}_{LP} ( jω - {jω}_{IF} ) = \frac{{ω}_{c}}{{ω}_{c} + j ( ω - {ω}_{IF} )} .$$

This frequency response H(jω) corresponds to a shift in the pole of the symmetric low-pass frequency response H_{LP}(jω) resulting in an asymmetric band-pass frequency response similar to the frequency response 216.

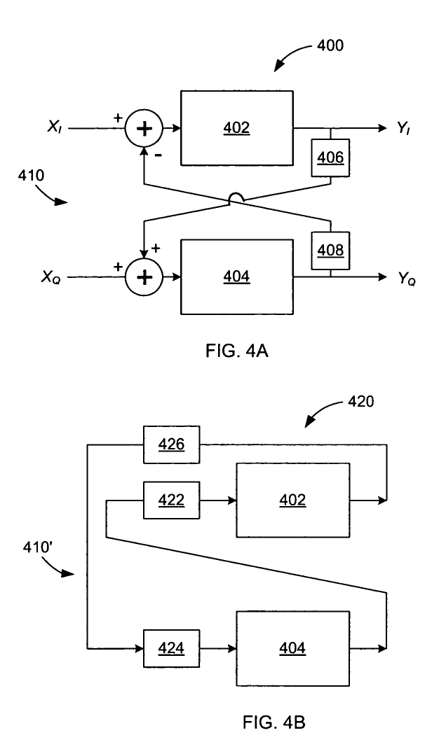

FIG. 4A shows an exemplary configuration of the reconfigurable circuitry 150 (FIG. 1C) to implement a polyphase band-pass filter 400 suitable for use as filter 110 in FIG. 1B. The polyphase band-pass filter 400 receives the two real input signals x_{I}(t) and x_{Q}(t). In this implementation, the processing components 402 and 404 are filter components interconnected by a connection network 410 that includes signal lines and other components such as adders and gain stages. The filters 402 and 404 each have a low-pass frequency response H_{LP}(jω). The gain components 406 and 408 each have a gain value of ω_{IF}/ω_{c}. The output of gain component 406 is added to the input signal x_{Q}(t) (indicated by the positive adder input terminals). The output of gain component 408 is subtracted from the input signal x_{I}(t) (indicated by the positive and negative adder input terminals). Equivalently, the output of the gain component 408 could be inverted and added to the input signal x_{I}(t).

The resulting effect of the polyphase filter 400 on the Fourier transforms X_{I}(jω) and X_{Q}(jω) of the input signals x_{I}(t) and x_{Q}(t), respectively, is given by
Y_{I}(jω)=H_{LP}(jω)X_{I}(jω)−ω_{IF}H_{LP}(jω)Y_{Q}(jω),
Y_{Q}(jω)=H_{LP}(jω)X_{Q}(jω)+ω_{IF}H_{LP}(jω)Y_{I}(jω).
These two equations can be used to derive the following equation:
Y_{I}(jω)+jY_{Q}(jω)=H_{LP}(jω−jω_{IF})(X_{I}(jω)+jX_{Q}(jω)),
which shows the equivalence between the single-input “complex” example above, and the present two-input “real” example.

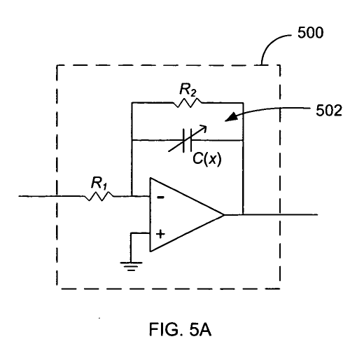

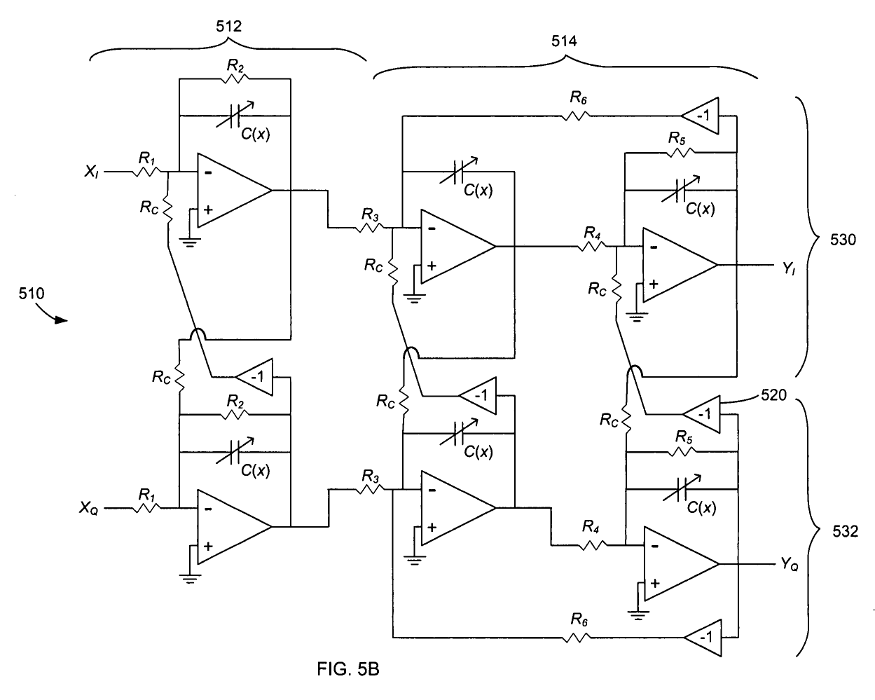

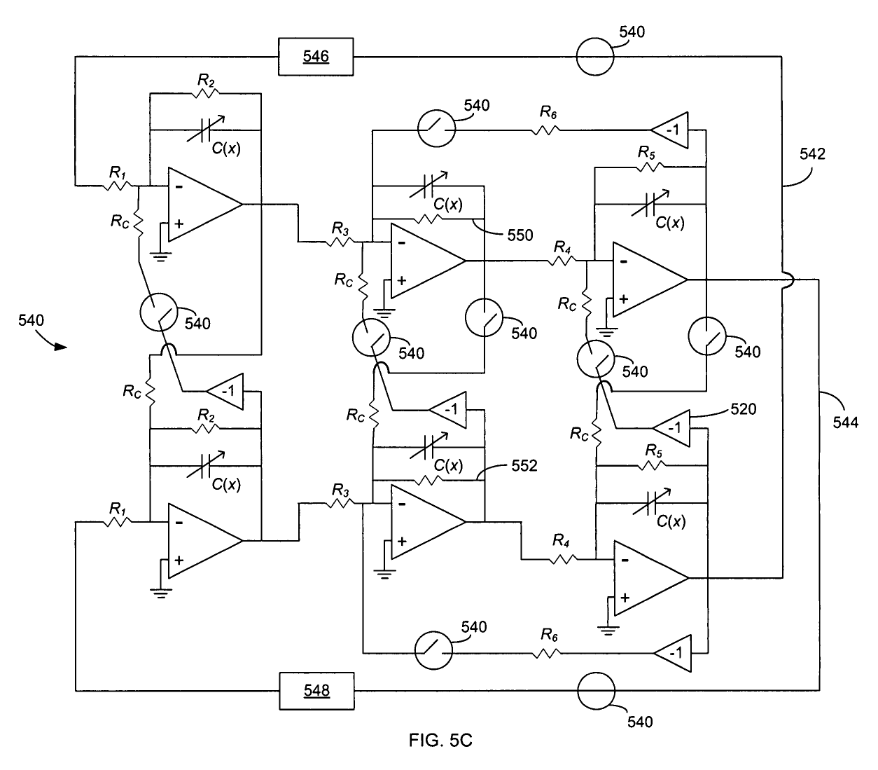

A variety of single stage or multi-stage filter designs can be used to implement a polyphase filter 110. The filter 400 shown in FIG. 4A is a single-stage polyphase filter having a single “I filter” 402 cross-coupled with a single “Q filter” 404. FIG. 5A shows an exemplary low-pass filter operational amplifier circuit 500 that can be used to implement the filters 402 and 404. The circuit 500 includes a unit capacitor 502 whose unit capacitance value C(x) can be varied to tune the low-pass filter cutoff frequency f_{c}. In an implementation of filter 400 using circuit 500 to implement the filters 402 and 404, the gain components 406 and 408 can be implemented by resistors.

FIG. 5B shows operational amplifier circuit 510 implementing a third-order multi-stage polyphase filter. A first stage 512 includes two cross-coupled low pass-filters, forming a first-order stage. A second stage 514 includes four cross-coupled low-pass filters, forming a second-order stage. The three I filters 530 and three Q filters 532 yield a composite a third-order Chebychev response for the circuit 510. The resistance R_{c} of the cross-coupling resistors and the unit capacitance value C(x) can be selected appropriately to set the center frequency

$${f}_{IF} = \frac{1}{2 π {R}_{c} C ( x )}$$

and the bandwidth

$$Δ f = 2 {f}_{c} ∝ \frac{1}{C ( x )}$$

of the polyphase filter. Since, as described above, the ratio of the bandwidth to the center frequency remains constant as the value of C(x) is tuned, the control input x can be used to tune both the bandwidth and center frequency once their ratio has been appropriately set (e.g., using trim resistor values in the circuit).

Other circuit designs can be used to implement the polyphase filter. For example, the filter can have any number of stages. The filter can have any type of pass-band shape using different filter types such as Chebychev, Butterworth, or Bessel filters. The filter can use “single-ended” signaling, as in the circuit 510, where signals are represented by a voltage on a single wire. Alternatively, the filter can use “double-ended” signaling, where differential signals are represented by a voltage difference between two wires. With double-ended signaling, the inverters 520 can be implemented by simply swapping the wires.

2.2 Filter Reconfiguration

FIG. 4B shows a configuration of reconfigurable circuitry 150 forming an oscillator circuit 420 from the same low-pass filter components 402 and 404 of the polyphase filter 400 by reconfiguring the connection network 410 into a new state represented by connection network 410′. When reconfiguring the connection network 410 to the connection network 410′, tuning circuitry 411 breaks (i.e., disconnects, switches off, or otherwise disables) the cross-coupling connections in the polyphase filter and connects the I filter (or filters) in series with the Q filter (or filters), cascading their respective frequency response functions yielding a round-trip response H_{RT}(jω). The tuning circuitry 411 also switches out the cross-coupling gain components 406 and 408 and switches in limiter components 422 and 424 (which also contribute to the round-trip response H_{RT}(jω)). This switching can be performed, for example, by applying control voltages to transistors at appropriate locations, such that one set of control voltages results in connection network 410, and another set of control voltages results in connection network 410′.

Oscillation will occur in the oscillator circuit 420 when the following conditions on the round-trip gain |H_{RT}(jω)| and round-trip phase [symbol] H_{RT}(jω) are met:
|H_{RT}(jω)|=1, [symbol]
H_{RT}(jω)=2πn,
where n is an integer. The limiters 422 and 424 contribute to achieving this condition by providing gain for small input signals. This gain encourages growth of a large signal from a small signal (e.g., noise) oscillating at a resonant frequency of the circuit 420.

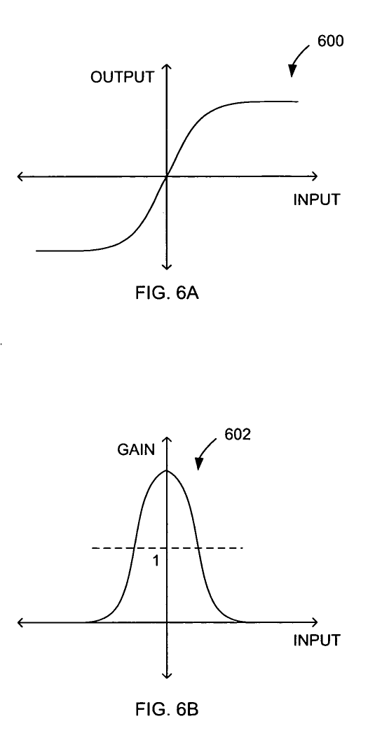

FIG. 6A shows the input-output transfer function 600 of the limiter components 422 and 424. Two limiter components 422 and 424 are included in this circuit 420 to maintain symmetry between the effects of the I filter 402 and effects of the Q filter 404 on the circuit 420. The limiter components 422 and 424 are selected to have similar transfer characteristics and are located in symmetric portions of the circuit 420. Such symmetry can contribute to the accuracy of the tuning procedure. Alternatively, other implementations may include only a single limiter component and still provide the gain needed for oscillation.

FIG. 6B shows the gain function 602 of the limiter components 422 and 424 (calculated as the derivative of the transfer function 600). The gain falls to zero for large amplitude oscillations. The small signal gain (i.e., slope of the transfer function 600 near zero) input is larger than one. A small signal oscillating at a frequency that satisfies the phase condition [symbol] H_{RT}(jω))=2πn will grow and settle to an amplitude that satisfies the gain condition |H_{RT}(jω)|=1.

The oscillation frequency at which these two oscillation conditions are satisfied is a function of the cutoff frequency f_{c} of the low-pass filters 402 and 404 and of the type of the filters (e.g., Butterworth). The relationship between the oscillation frequency and bandwidth Δf=2f_{c} of the polyphase filter 400 is therefore predetermined and can be used in determining how to tune the polyphase filter 400 based on the oscillation frequency measured by the tuning circuitry 411.

Optionally, the circuit 420 can include a phase element 426 to shift the oscillation frequency. For example, the phase element 426 can be an inverter (contributing 180° to the round-trip phase) which can be implemented in a way that does not significantly affect symmetry between the effects of the I filter 402 and effects of the Q filter 404 on the circuit 420.

FIG. 5C shows an oscillator circuit 540 formed after reconfiguring circuit 510 into an oscillator. Cross-coupling connections are disconnected by opening switches 540. New connections 542 and 544 are formed by closing switches 540. The new connections add limiter components 546 and 548 to the oscillator circuit 540. The filter components of the circuit 510 can also be reconfigured. In this example, resistors 550 and 552 are added to two of the filters in the second stage 514 of the circuit 510.

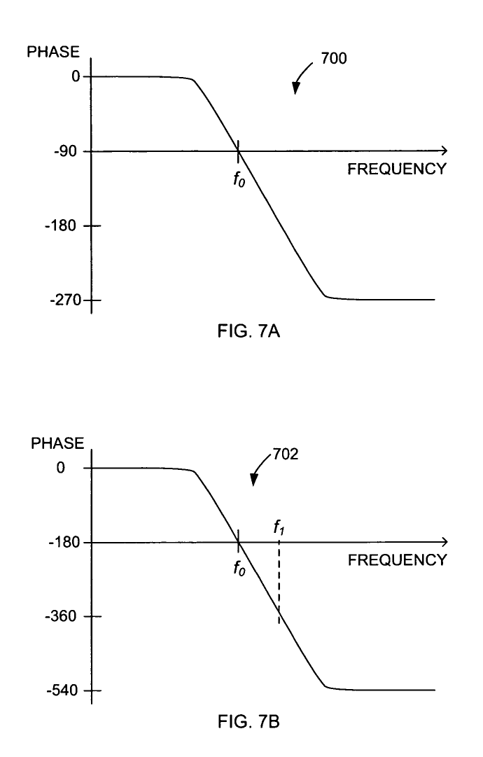

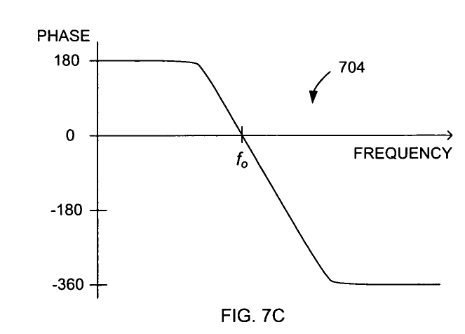

FIG. 7A shows an exemplary phase response 700 for a signal passing through the three I filters 530 (or the three Q filters 532) of circuits 510 and 540 (in a phase vs. frequency log-log plot). FIG. 7B shows a phase response 702 resulting from connecting the I filters 530 (the “I channel”) and Q filters 532 (the “Q channel”) in series. In this phase response 702, phase condition is satisfied not at a frequency f₁, but also at low frequencies, which provides positive feedback for DC fluctuations that could cause the reconfigured oscillator circuit 540 to latch up. FIG. 7C shows a phase response 704 that results from including an inverter in the reconfigured oscillator circuit 540. The inverter provides negative feedback at low frequencies. The inclusion of an inverter also lowers the oscillation frequency to a frequency f₀ that is within the pass-band of the low-pass filters (e.g., the 3 dB pass-band). This provides the benefit that the tuning procedure is not greatly influenced by imperfections far above the pass-band and also calls for only modest gain within the oscillation loop (e.g., from the limiter components) to ensure robust oscillation.

It is to be understood that the foregoing description is intended to illustrate and not to limit the scope of the invention, which is defined by the scope of the appended claims. Other embodiments are within the scope of the following claims.

What is claimed is:

1. An apparatus, comprising:
a first processing component having an input port and an output port;
a second processing component having an input port and an output port; and
a reconfigurable connection network coupled to the ports having at least two connection states including
a first state in which the first and second processing components are connected to form at least part of a polyphase filter, and
a second state in which the first and second processing components are connected to form at least part of an oscillator.

2. The apparatus of claim 1, further comprising tuning circuitry configured to:
switch between the connection states,
measure an operating characteristic of the oscillator, and
tune an operating characteristic of the polyphase filter based at least in part on the measured operating characteristic of the oscillator.

3. The apparatus of claim 2, where the operating characteristic of the oscillator comprises an oscillation frequency of the oscillator.

4. The apparatus of claim 3, where the operating characteristic of the polyphase filter comprises phase shifts imparted by the first and second processing components to a signal at an operating frequency.

5. The apparatus of claim 4, where tuning the operating characteristic of the polyphase filter comprises tuning the phase shifts based on a relationship between the oscillation frequency and the operating frequency.

6. The apparatus of claim 2, where tuning the operating characteristic of the polyphase filter comprises tuning tunable elements in the first and second processing components.

7. The apparatus of claim 6, where the tunable elements comprise tunable capacitors.

8. The apparatus of claim 7, where the tunable capacitors comprise unit capacitors each having a capacitance that is a multiple of a unit capacitance value.

9. The apparatus of claim 1, where, in the first state, the input port of the first processing component receives a first input signal and the input port of the second processing component receives a second input signal, and a first connection couples the output port of the first processing component to the input port of the second processing component and a second connection couples the output port of the second processing component to the input port of the first processing component.

10. The apparatus of claim 9, where the first input signal comprises an in-phase signal derived from a received signal modulated by a first sinusoidal signal, and the second input signal comprises a quadrature-phase signal derived from the received signal modulated by a second sinusoidal signal that has a 90 degree phase shift relative to the first sinusoidal signal.

11. The apparatus of claim 9, where, in the first state, the first connection includes a 180 degree phase shift relative to the second connection.

12. The apparatus of claim 9, further comprising:
a third processing component having an input port and an output port; and
a fourth processing component having an input port and an output port;
where
in the first state, ports of the third and fourth processing component are connected to form at least part of the polyphase filter; and
in the second state, the first, second, third, and fourth processing component are connected to form at least part of the oscillator.

13. The apparatus of claim 12, where, in the first state, the input port of the third processing component receives a signal from the output port of the first processing component and the input port of the fourth processing component receives a signal from the output port of the second processing component, and a third connection couples the output port of the third processing component to the input port of the fourth processing component and a fourth connection couples the output port of the fourth processing component to the input port of the third processing component.

14. The apparatus of claim 1, where the first and second processing components each comprise a filter.

15. The apparatus of claim 14, where the first and second processing components each comprise a low-pass filter.

16. The apparatus of claim 1, where the input ports and output ports of the first and second processing components couple differential signals.

17. The apparatus of claim 1, further comprising at least a first gain element in the oscillator.

18. The apparatus of claim 17, where the gain element comprises a limiter.

19. The apparatus of claim 17, further comprising a second gain element in the oscillator, where the position of the second gain element with respect to the second processing component is symmetric with the position of the first gain element with respect to the first processing component.

20. The apparatus of claim 1, further comprising a phase element in the oscillator that provides negative feedback for low frequencies.

21. A method for calibrating a filter, comprising:
configuring a connection network coupled to input and output ports of first and second processing components into a first state in which the first and second processing components are connected to form at least part of an oscillator; and
reconfiguring the connection network into a second state in which the first and second processing components are connected to form at least part of a polyphase filter.

22. The method of claim 21, further comprising:
measuring an operating characteristic of the oscillator; and
tuning an operating characteristic of the polyphase filter based at least in part on the measured operating characteristic of the oscillator.

23. A system for calibrating a filter, comprising:
means for configuring a connection network coupled to input and output ports of first and second processing components into a first state in which the first and second processing components are connected to form at least part of an oscillator; and
means for reconfiguring the connection network into a second state in which the first and second processing components are connected to form at least part of a polyphase filter.

24. The system of claim 23, further comprising:
means for measuring an operating characteristic of the oscillator; and
means for tuning an operating characteristic of the polyphase filter based at least in part on the measured operating characteristic of the oscillator.
